(19) United States
(12) Patent Application Publication
(10) Pub. No.: US 2024/0271267 A1
(43) Pub. Date: Aug. 15, 2024

(54) DEPOSITION APPARATUS

(71) Applicant: Samsung Display Co., Ltd., Yongin-si (KR)

(72) Inventors: JUNGHYUN AHN, Yongin-si (KR); JAESUK MOON, Yongin-si (KR); SEUNGJIN LEE, Yongin-si (KR)

(73) Assignee: Samsung Display Co., Ltd., Yongin-si (KR)

(21) Appl. No.: 18/504,026

(22) Filed: Nov. 7, 2023

(30) Foreign Application Priority Data
Feb. 14, 2023 (KR) 10-2023-0019569

(51) Int. Cl. C23C 14/04; H10K 71/16

(52) U.S. Cl. CPC C23C 14/042; H10K 71/166

(57) ABSTRACT

A deposition apparatus includes a mask frame having a frame shape, masks disposed on the mask frame, extending in a selected direction, disposed in an intersection direction intersecting the selected direction, and including cell areas, a magnet plate disposed on the masks, and magnet parts connected to a lower surface of the magnet plate. At least one of the plurality of magnet parts moves in the selected direction.

### CROSS-REFERENCE TO RELATED APPLICATION(S)

This application claims priority to and benefits of Korean Patent Application No. 10-2023-0019569 under 35 U.S.C. § 119, filed on Feb. 14, 2023, in the Korean Intellectual Property Office, the entire contents of which are incorporated herein by reference.

### BACKGROUND

### 1. Technical Field

The disclosure relates to a deposition apparatus.

### 2. Description of the Related Art

An organic light emitting diode display (OLED) is being spotlighted as a next generation flat display device for its superior brightness and viewing angle. Since the organic light emitting diode display does not need to include a separate light source different from a liquid crystal display, it is manufactured with a thin thickness and is light weight. The organic light emitting diode display has properties, such as low power consumption, high brightness, fast response speed, etc.

The organic light emitting diode display may include organic light emitting elements that may include an anode, an organic light emitting layer, and a cathode. Holes and electrons are injected into the organic light emitting layer through the anode and the cathode and are recombined in the organic light emitting layer to generate excitons. The organic light emitting elements emit light in case that an excited state of the excitons returns to a ground state.

In case that the organic light emitting elements are manufactured, a mask is disposed on a substrate, and an organic material used to form the organic light emitting layer is provided on the substrate through openings defined through the mask. Snice the mask may include metal and is formed very thin, it does not stay flat. A mask frame that fixes the mask and magnet units that suction-holds the mask flat to the substrate are used to allow the mask to stay flat. The magnet units are fixed to a magnet plate.

However, in a case where the mask is aligned parallel to a direction in which the magnet units are arranged, a repulsive force occurs between the magnet units and the mask. The mask is not suction-held flat to the substrate.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a deposition apparatus including magnet units (or parts) that move to allow polarities thereof to be disposed in a direction intersecting a direction in which masks extend.

Embodiments provide a deposition apparatus that may include a mask frame having a frame shape; a plurality of masks disposed on the mask frame, extending in a selected direction, disposed in an intersection direction intersecting the selected direction, and each of the plurality of masks including cell areas ; a magnet plate disposed on the plurality of masks; and a plurality of magnet parts connected to a lower surface of the magnet plate. At least one of the plurality of magnet parts moves in the selected direction.

The plurality of magnet parts may comprise: a plurality of first magnet parts disposed to allow first polarities of the plurality of first magnet parts to face the plurality of masks; and a plurality of second magnet parts disposed to allow second polarities of the plurality of second magnet parts to face the plurality of masks, and the plurality of first magnet parts and the plurality of second magnet parts are disposed in the selected direction and the intersection direction before the at least one of the plurality of magnet parts moves.

In case that the at least one of the plurality of magnet parts may move, the plurality of first magnet parts overlapping the cell areas may be disposed in the intersection direction, the plurality of second magnet parts overlapping the cell areas may be disposed in the intersection direction, and the plurality of first magnet parts may be alternately disposed with the plurality of second magnet parts in the selected direction.

The intersection direction may be defined as a first direction, the selected direction may be defined as a second direction, the plurality of first magnet parts and the plurality of second magnet parts disposed in even-numbered rows among rows corresponding to the second direction move in the second direction, and the second direction corresponds to the even-numbered rows.

In case that the plurality of first magnet parts and plurality of second magnet parts disposed in the even-numbered rows may move in the second direction, the plurality of first magnet parts may be disposed in the first direction, the plurality of second magnet parts may be disposed in the first direction, and the plurality of first magnet parts may be alternately disposed with the plurality of second magnet parts in the second direction.

The intersection direction may be defined as a first direction, the selected direction may be defined as a second direction, the plurality of first magnet parts and the plurality of second magnet parts disposed in odd-numbered rows among rows corresponding to the second direction move in the second direction, and the second direction corresponds to the odd-numbered rows.

In case that the plurality of first magnet parts and the plurality of second magnet parts in the odd-numbered rows move in the second direction, the plurality of first magnet parts may be disposed in the first direction, the plurality of second magnet parts may be disposed in the first direction, and the plurality of first magnet parts may be alternately disposed with the second magnet parts in the second direction.

The selected direction may be defined as a first direction, the intersection direction may be defined as a second direction, the plurality of first magnet parts and the plurality of second magnet parts disposed in even-numbered columns among columns corresponding to the first direction move in the first direction, and the first direction corresponds to the even-numbered columns.

In case that the plurality of first magnet parts and the plurality of second magnet parts may be disposed in the even-numbered columns move in the first direction, the plurality of first magnet parts may be disposed in the second direction, the plurality of second magnet parts may be disposed in the second direction, and the plurality of first magnet parts may be alternately disposed with the plurality of second magnet parts in the first direction.

The selected direction may be defined as a first direction, the intersection direction may be defined as a second direction, the plurality of first magnet parts and the plurality of second magnet parts disposed in odd-numbered columns among columns corresponding to the first direction move in the first direction, and the first direction corresponds to the odd-numbered columns.

In case that the plurality of first magnet parts and the plurality of second magnet parts may be disposed in the odd-numbered columns move in the first direction, the plurality of first magnet parts may be disposed in the second direction, the plurality of second magnet parts may be disposed in the second direction, and the plurality of first magnet parts may be alternately disposed with the plurality of second magnet parts in the first direction.

The plurality of first magnet parts may have a same area as the plurality of second magnet parts in a plan view.

The deposition apparatus may further comprise a cooling plate disposed between the plurality of masks and the magnet plate.

The deposition apparatus may further comprise a driver connected to an upper surface of the magnet plate and extending in a direction intersecting the selected direction and the intersection direction.

Embodiments provide a deposition apparatus that may include a mask frame having a frame shape; a plurality of masks disposed on the mask frame, extending in a selected direction, disposed in an intersection direction intersecting the selected direction, and each of the plurality of masks including cell areas ; a magnet plate disposed on the plurality of masks, and a plurality of magnet parts connected to a lower surface of the magnet plate. The plurality of magnet parts may include a plurality of first magnet parts disposed to allow first polarities thereof to face the plurality of masks and a plurality of second magnet parts disposed to allow second polarities thereof to face the plurality of masks, and a direction in which the plurality of first magnet parts and the plurality of second magnet parts may be disposed may be changed.

The plurality of first magnet parts and the plurality of second magnet parts may be disposed in the selected direction and the intersection direction before an arrangement direction of the plurality of first magnet parts and the plurality of second magnet parts is changed.

The plurality of first magnet parts and the plurality of second magnet parts may move in the selected direction in case that the arrangement direction of the plurality of first magnet parts and the plurality of second magnet parts is changed.

In case that the arrangement direction of the plurality of first magnet parts and the plurality of second magnet parts is changed, the plurality of first magnet parts may be disposed in the intersection direction, the plurality of second magnet parts may be disposed in the intersection direction, and the plurality of first magnet parts may be alternately disposed with the plurality of second magnet parts in the selected direction.

The intersection direction may be defined as a first direction, the selected direction may be defined as a second direction, and in case that the arrangement direction of the plurality of first magnet parts and the plurality of second magnet parts is changed, the plurality of first magnet parts may be disposed in the first direction, the plurality of second magnet parts may be disposed in the first direction, and the plurality of first magnet parts may be alternately disposed with the plurality of second magnet parts in the second direction.

The selected direction may be defined as a first direction, the intersection direction may be defined as a second direction, and in case that the arrangement direction of the plurality of first magnet parts and the plurality of second magnet parts is changed, the plurality of first magnet parts may be disposed in the second direction, the plurality of second magnet parts may be disposed in the second direction, and the plurality of first magnet parts may be alternately disposed with the plurality of second magnet parts in the first direction.

According to the above, the magnet units move in the one direction or the intersection direction according to the extension direction of the masks. Thus, the magnet units are arranged to allow the polarities thereof to be arranged in the direction intersecting the extension direction of the masks, and a repulsive force does not occur between the magnet units and the masks. Accordingly, defects caused by a loose attachment between the masks and the substrate are reduced in a deposition process.

### BRIEF DESCRIPTION OF THE DRAWINGS

The above and other advantages of the disclosure will become readily apparent by reference to the following detailed description when considered in conjunction with the accompanying drawings wherein:

FIG. 1 is a schematic perspective view of a deposition apparatus according to an embodiment;

FIG. 2 is a schematic plan view of a lower surface of a magnet plate shown in FIG. 1;

FIG. 3 is a schematic perspective view of a mask frame and first masks shown in FIG. 1;

FIGS. 4A to 4F are views illustrating a method of depositing a deposition material on a substrate using the deposition apparatus shown in FIG. 1;

FIG. 5 is a schematic perspective view of a deposition apparatus in which masks different from those of FIG. 1 are provided;

FIGS. 6A to 6H are views illustrating a method of depositing a deposition material on a substrate using the deposition apparatus shown in FIG. 5;

FIG. 7 is a schematic plan view of a display panel manufactured using masks shown in FIGS. 1 and 5;

FIG. 8 is a schematic cross-sectional view of a pixel shown in FIG. 7; and

FIG. 9 is a schematic cross-sectional view illustrating a deposition process shown in FIG. 4F.

### DETAILED DESCRIPTION OF THE EMBODIMENTS

Features of the disclosure and methods of accomplishing the same may be understood more readily by reference to the following detailed description of embodiments and the accompanying drawings. The disclosure may, however, be embodied in many different forms and should not be construed as being limited to the embodiments set forth herein. Rather, these embodiments are provided so that this disclosure will be through and complete and will fully convey the disclosure to those skilled in the art, and the disclosure will be defined by the appended claims. Like reference numerals denote like elements throughout the specification.

In the disclosure, it will be understood that when an element or layer is referred to as being “on”, “connected to” or “coupled to” another element or layer, it can be directly on, connected or coupled to the other element or layer or intervening elements or layers may be present.

It will be understood that the terms “connected to” or “coupled to” may include a physical or electrical connection or coupling.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

The term “overlap” or “overlapped” means that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the disclosure.

Embodiments described in the disclosure are described with reference to schematic plan views and schematic cross-sectional views. Accordingly, shapes of the views may vary depending on manufacturing technologies and/or tolerances. Thus, embodiments are not limited to shown illustrated forms and also include variations in form produced according to manufacturing processes. Therefore, regions illustrated in the drawings are examples, and the shapes of the regions illustrated in the drawings are intended to illustrate the illustrated shapes of the regions of elements and not to limit the scope of the disclosure.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments will be described with reference to accompanying drawings.

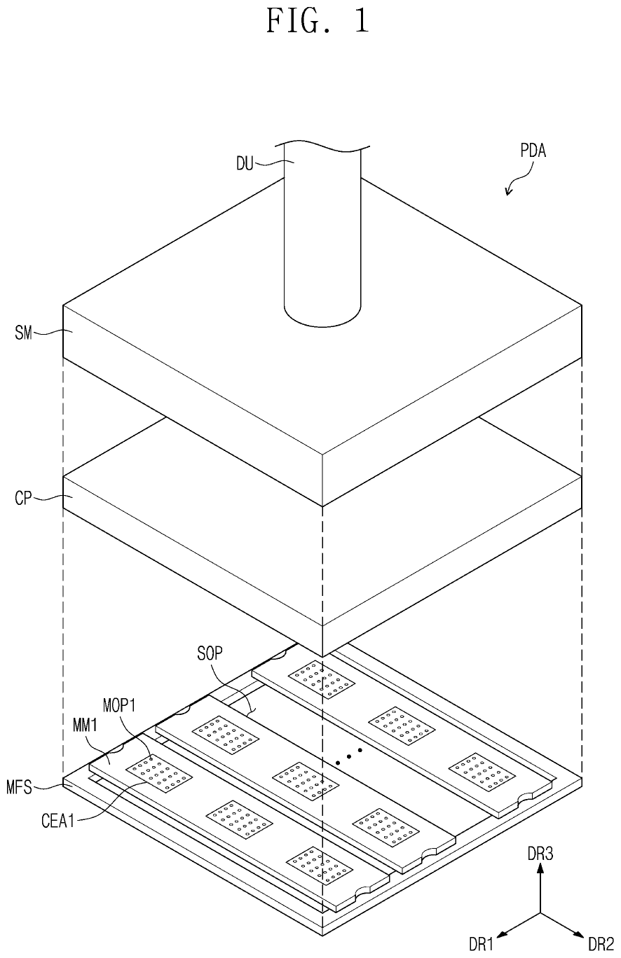

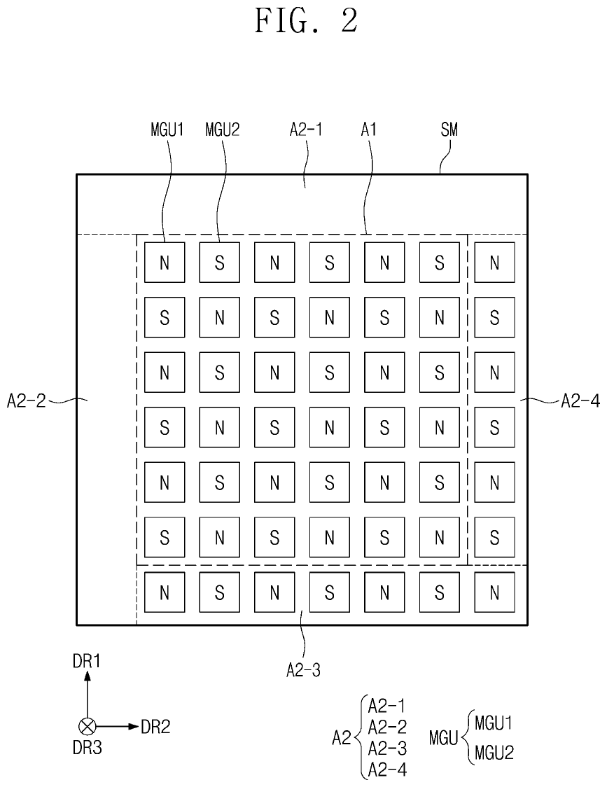

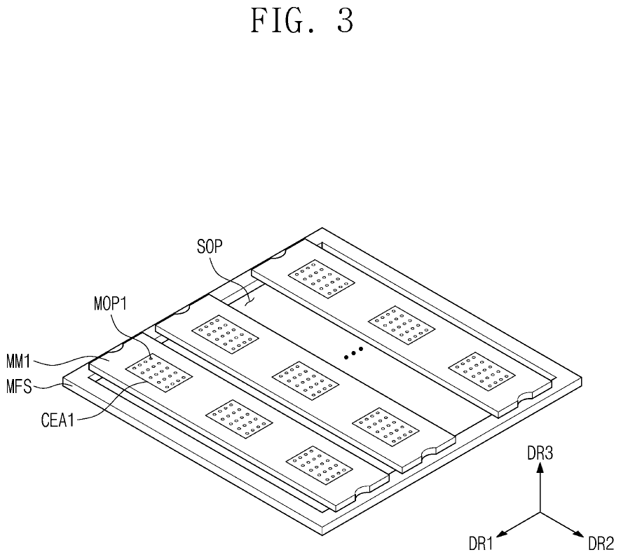

FIG. 1 is a schematic perspective view of a deposition apparatus PDA according to an embodiment. FIG. 2 is a schematic plan view of a lower surface of a magnet plate SM shown in FIG. 1. FIG. 3 is a schematic perspective view of a mask frame MFS and first masks MM1 shown in FIG. 1.

Referring to FIGS. 1, 2, and 3, the deposition apparatus PDA may include the mask frame MFS, the first masks MM1, a cooling plate CP, the magnet plate SM, and a driving unit DU.

The mask frame MFS may have a quadrangular shape with side surfaces extending in a first direction DR1 and side surfaces extending in a second direction DR2 intersecting the first direction DR1. The mask frame MFS may have a quadrangular frame shape, however, the shape of the mask frame MFS should not be limited thereto or thereby.

A mask opening SOP may be defined through the mask frame MFS. The mask opening SOP may have a quadrangular shape, however, the shape of the mask opening SOP should not be limited to the quadrangular shape.

The mask frame MFS may include a metal material. As an example, the mask frame MFS may include invar or stainless steel.

Hereinafter, a direction intersecting a plane defined by the first and second directions DR1 and DR2 is referred to as a third direction DR3. The third direction DR3 may be perpendicular to the plane defined by the first and second directions DR1 and DR2. In the disclosure, the expression “when viewed in a plane” or “when viewed in a plan view” may mean a state of being viewed in the third direction DR3.

The first masks MM1 may be disposed on the mask frame MFS. Two sides of the first masks MM1 may be connected to the mask frame MFS. As an example, the first masks MM1 may be connected to the mask frame MFS by a laser welding method.

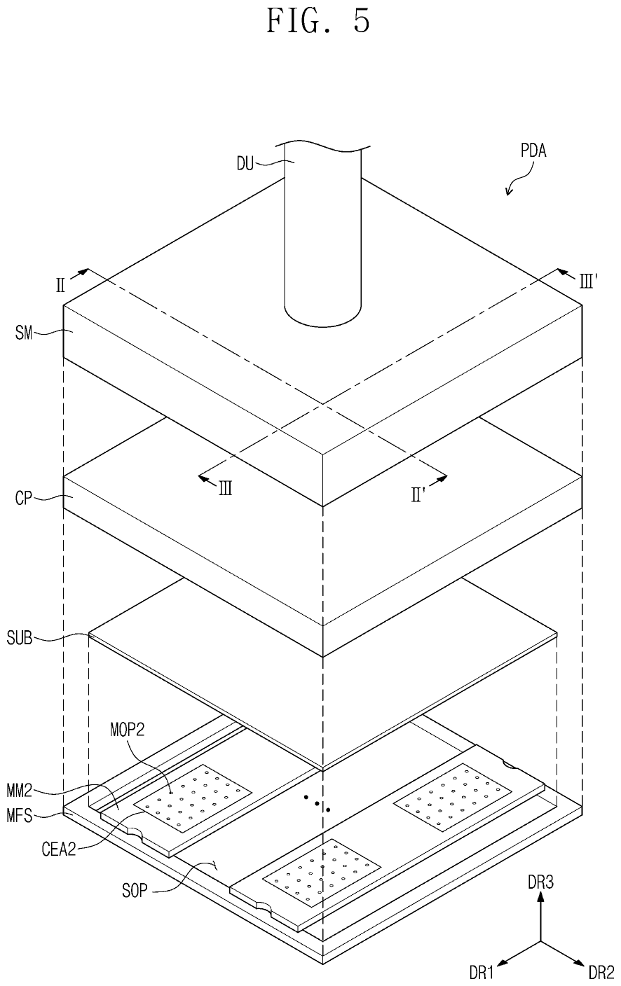

The first masks MM1 may be arranged (or disposed) in the first direction DR1 and may extend in the second direction DR2. The first masks MM1 may extend in one direction (or a selected direction). The first masks MM1 may be arranged in an intersection direction. Hereinafter, the one direction may be defined as an extension direction of the first masks MM1 and second masks MM2 described with reference to FIG. 5. The intersection direction may be defined as an arrangement direction of the first masks MM1 and the second masks MM2 described with reference to FIG. 5. The intersection direction may intersect the one direction. As an example, in FIG. 1, the one direction may correspond to the second direction DR2, and the intersection direction may correspond to the first direction DR1.

The first masks MM1 may include a metal material. As an example, each of the first masks MM1 may be a fine metal mask. Each of the first masks MM1 may have a rectangular shape with short sides in the first direction DR1 and long sides in the second direction DR2.

Each of the first masks MM1 may include first cell areas CEA1 defined in an upper surface thereof. As an example, three first cell areas CEA1 may be defined in the upper surface of each of the first masks MM1, however, the number of the first cell areas CEA1 should not be limited to three.

The first cell areas CEA1 may be arranged in the one direction. The first cell areas CEA1 may be arranged in the second direction DR2. When viewed in the plane, the first cell areas CEA1 may be arranged to overlap the mask opening SOP. When viewed in the plane, the first cell areas CEA1 may not overlap the mask frame MFS.

Each of the first cell areas CEA1 may have a polygonal shape. As an example, each of the first cell areas CEA1 may have a rectangular shape with short sides in the first direction DR1 and long sides in the second direction DR2.

First cell openings MOP1 may be defined in each of the first cell areas CEA1. The first cell openings MOP1 may be arranged in the first direction DR1 and the second direction DR2. When viewed in the plane, the first cell openings MOP1 may overlap the mask opening SOP.

As an example, sixteen first cell openings MOP1 may be defined in each of the first cell areas CEA1, however, the number of the first cell openings MOP1 should not be limited thereto or thereby.

The cooling plate CP may be disposed above the mask frame MFS and the first masks MM1. The first masks MM1 may be disposed between the cooling plate CP and the mask frame MFS. The cooling plate CP may have a hexahedral shape including upper and lower surfaces defined by the first direction DR1 and the second direction DR2. However, the shape of the cooling plate CP should not be limited thereto or thereby and may be provided in various shapes.

The magnet plate SM may be disposed above the cooling plate CP. The cooling plate CP may be disposed between the first masks MM1 and the magnet plate SM. The magnet plate SM may have a hexahedral shape including upper and lower surfaces defined by the first direction DR1 and the second direction DR2. However, the shape of the magnet plate SM should not be limited thereto or thereby and may be provided in various shapes.

The lower surface of the magnet plate SM may have a planar shape defined by the first direction DR1 and the second direction DR2. The lower surface of the magnet plate SM may include a first area A1 and a second area A2. The first area A1 may overlap the mask opening SOP. The second area A2 may overlap the mask frame MFS. The second area A2 may not overlap the mask opening SOP. The second area A2 may surround the first area A1.

The second area A2 may include a second-first area A2-1, a second-second area A2-2, a second-third area A2-3, and a second-fourth area A2-4. The second-first area A2-1 and the second-third area A2-3 may extend in the second direction DR2. The second-second area A2-2 and the second-fourth area A2-4 may extend in the first direction DR1.

When viewed in the plane, the second-first area A2-1 and the second-third area A2-3 may be respectively disposed adjacent to edges of the magnet plate SM, which are opposite to each other in the first direction DR1. When viewed in the plane, the second-second area A2-2 and the second-fourth area A2-4 may be respectively disposed adjacent to edges of the magnet plate SM, which are opposite to each other in the second direction DR2.

The second-second area A2-2 may extend from one side (or a side) of both sides of the second-first area A2-1, which are opposite to each other in the second direction DR2. The second-fourth area A2-4 may extend from the other side of the second-first area A2-1. The one side of the second-first area A2-1 may be defined as a side opposite to the other side adjacent to magnet units MGU. One side of both sides of the second-third area A2-3, which are opposite to each other in the second direction DR2, may be disposed adjacent to the second-second area A2-2. The other side of the second-third area A2-3 may be disposed adjacent to the second-fourth area A2-4. The one side of the second-third area A2-3 may be defined as a side adjacent to the second-second area A2-2.

A length in the second direction DR2 of the second-first area A2-1 may be greater than a length in the first direction DR1 of the second-second area A2-2. The length in the first direction DR1 of the second-second area A2-2 may be equal to a length in the second direction DR2 of the second-third area A2-3. The length in the first direction DR1 of the second-second area A2-2 may be greater than a length in the first direction DR1 of the second-fourth area A2-4. The length in the second direction DR2 of the second-third area A2-3 may be greater than the length in the first direction DR1 of the second-fourth area A2-4.

The deposition apparatus PDA may include the magnet units MGU. The magnet units MGU may be disposed on the lower surface of the magnet plate SM. When viewed in the plane, the magnet units MGU may be disposed in the first area A1, the second-third area A2-3, and the second-fourth area A2-4. The magnet units MGU may not be disposed in the second-first area A2-1 and the second-second area A2-2.

When viewed in the plane, the magnet units MGU may have a quadrangular shape. However, the shape of the magnet units MGU should not be limited to the quadrangular shape and may have a variety of shapes. As an example, the magnet units MGU may have substantially the same size as each other.

The magnet units MGU may include a magnetic material having a magnetic force. Each of the magnet units MGU may have a first polarity and a second polarity different from the first polarity. As an example, the first polarity may be defined as a magnet's north (N) pole, and the second polarity may be defined as a magnet's south (S) pole.

The magnet units MGU may include first magnet units MGU1 and second magnet units MGU2. The first magnet units MGU1 may be defined as magnet units MGU arranged to allow the first polarities to face the first masks MM1. The second magnet units MGU2 may be defined as magnet units arranged to allow the second polarities to face the first masks MM1.

When viewed in the plane, the first magnet units MGU1 and the second magnet units MGU2 may be arranged in the first direction DR1 and the second direction DR2. The first magnet units MGU1 and the second magnet units MGU2 may be arranged in the one direction and the intersection direction.

The first magnet units MGU1 may be alternately arranged with the second magnet units MGU2. For example, polarities of the magnet units MGU adjacent to each other in the first direction DR1 and the second direction DR2, which face the first masks MM1, may be different from each other.

When viewed in the plane, each of the first magnet units MGU1 and each of the second magnet units MGU2 may have a quadrangular shape. However, the shape of the first and second magnet units MGU1 and MGU2 should not be limited to the quadrangular shape and may have a variety of shapes. As an example, each of the first magnet units MGU1 and each of the second magnet units MGU2 may have substantially the same area as each other.

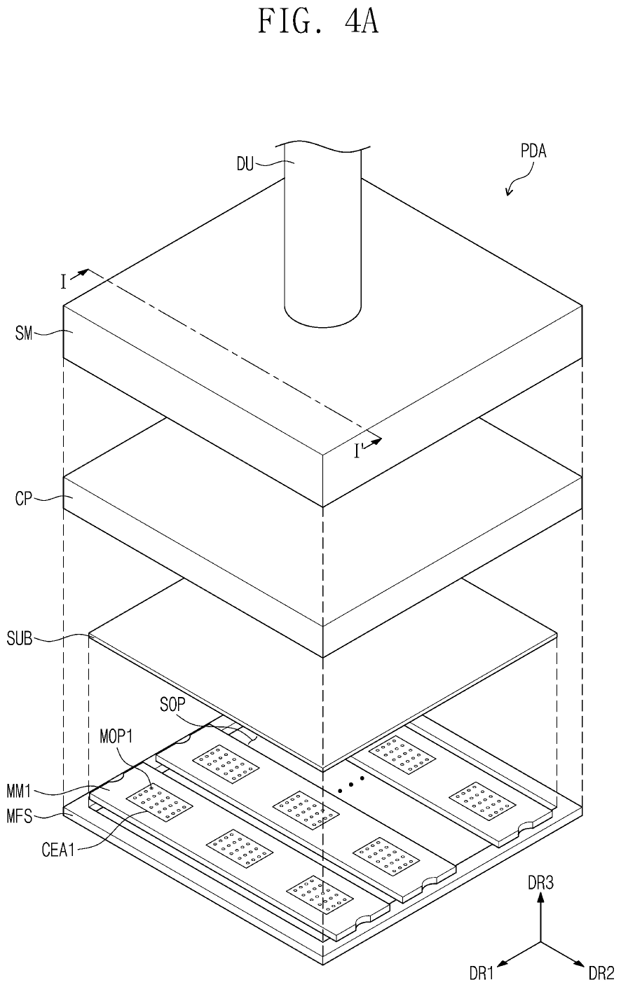

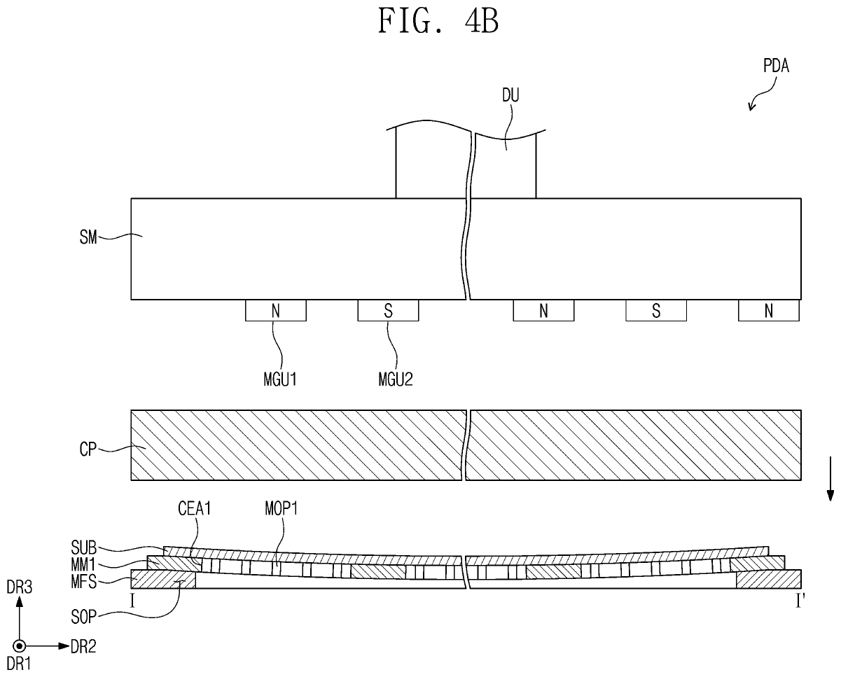

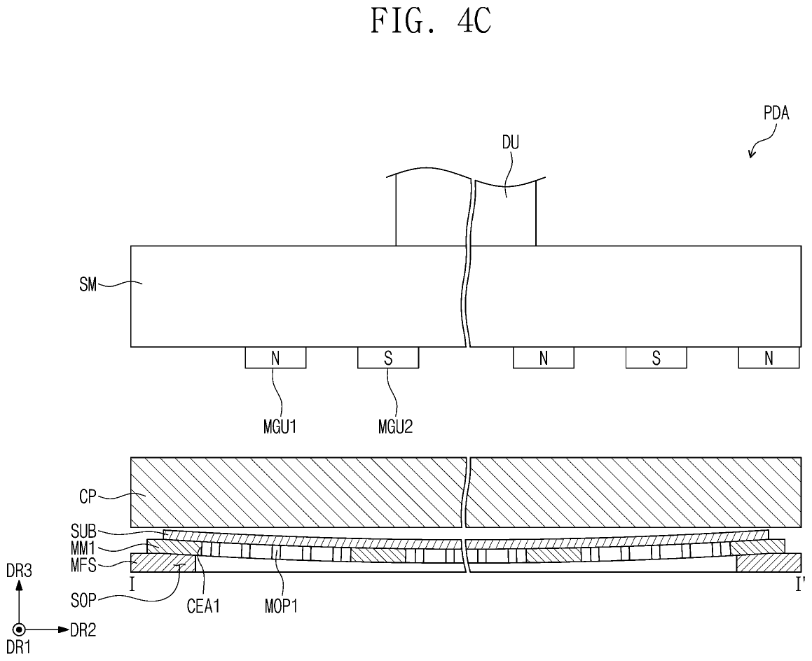

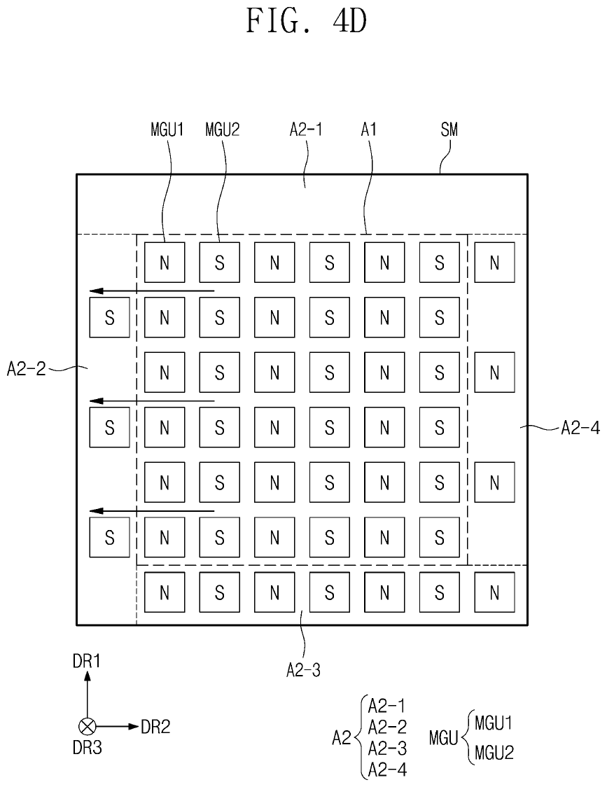

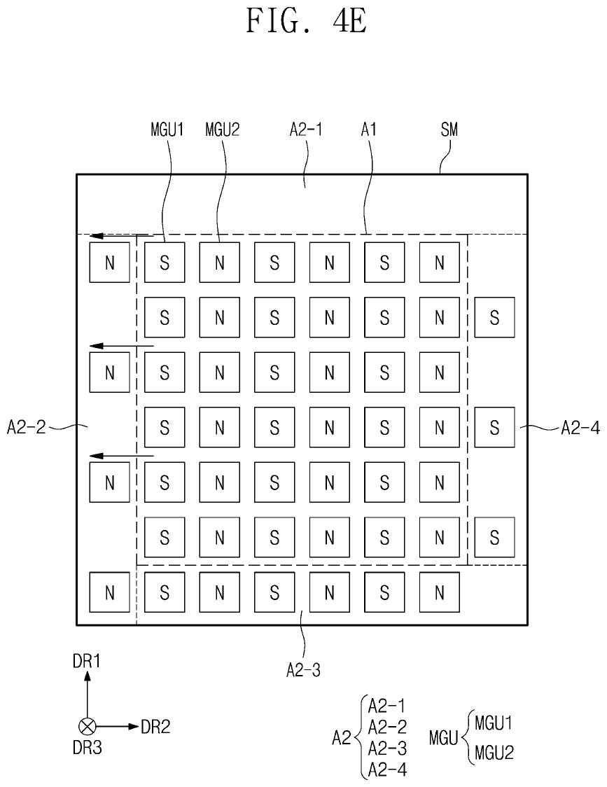

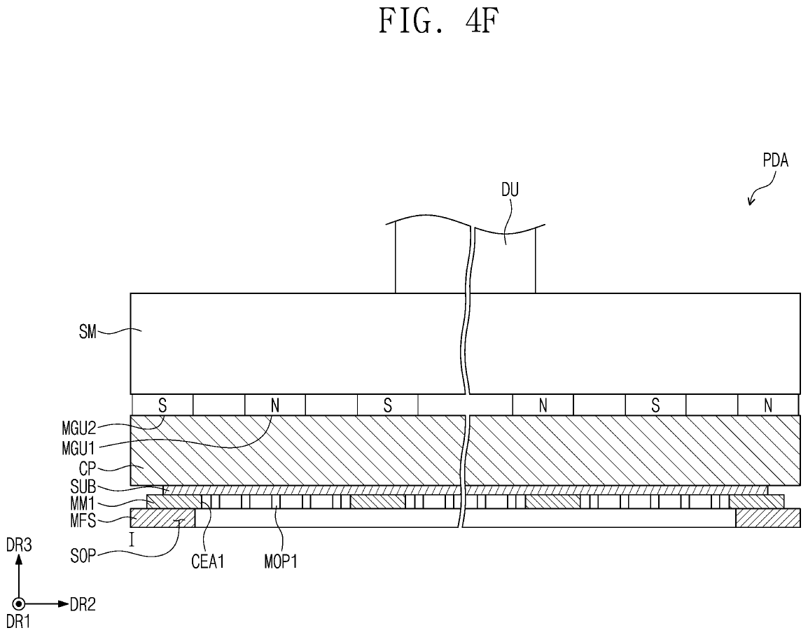

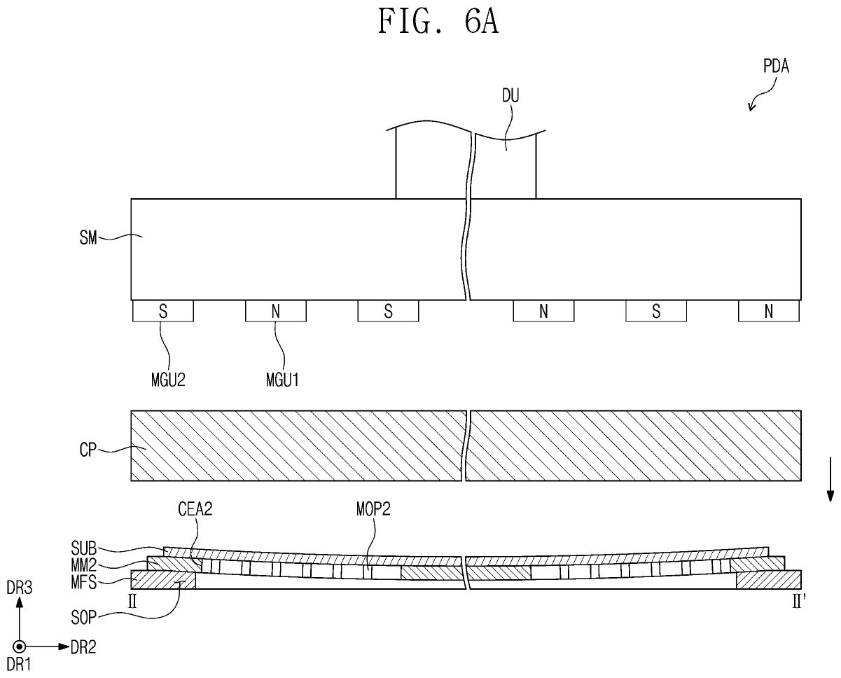

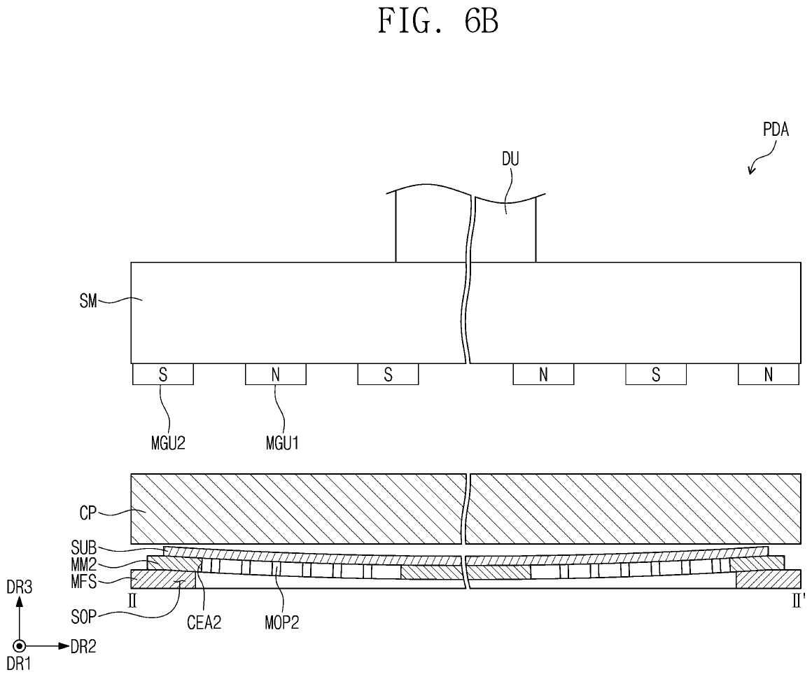

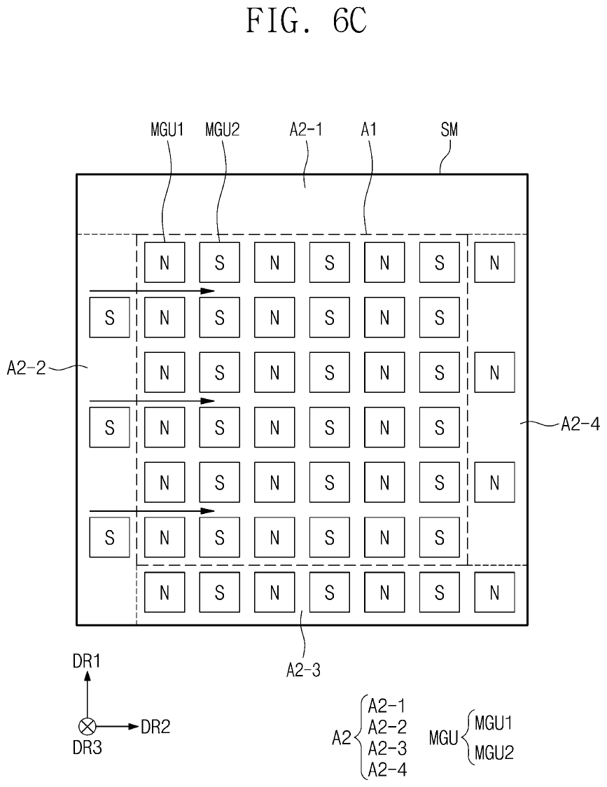

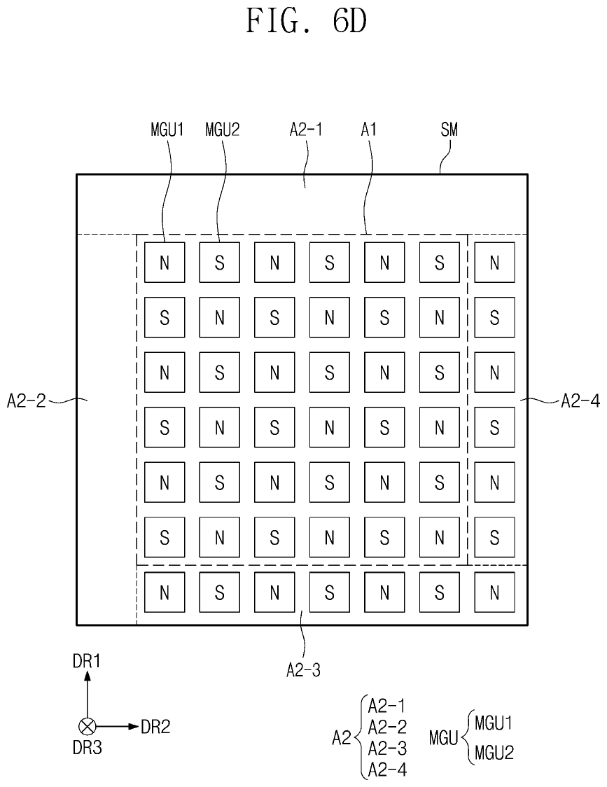

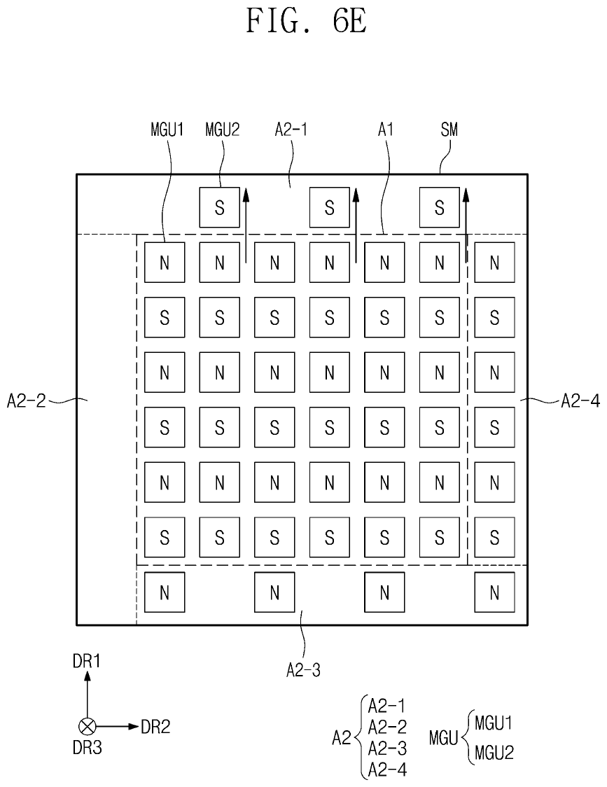

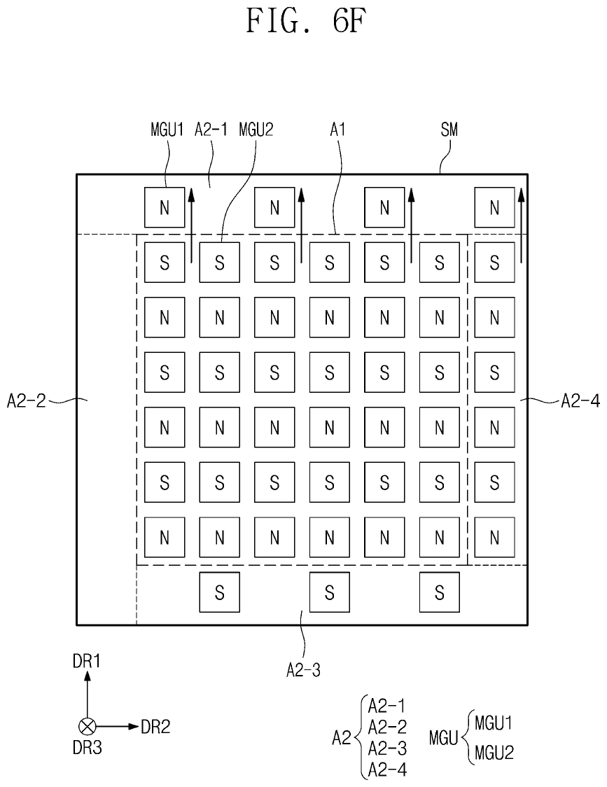

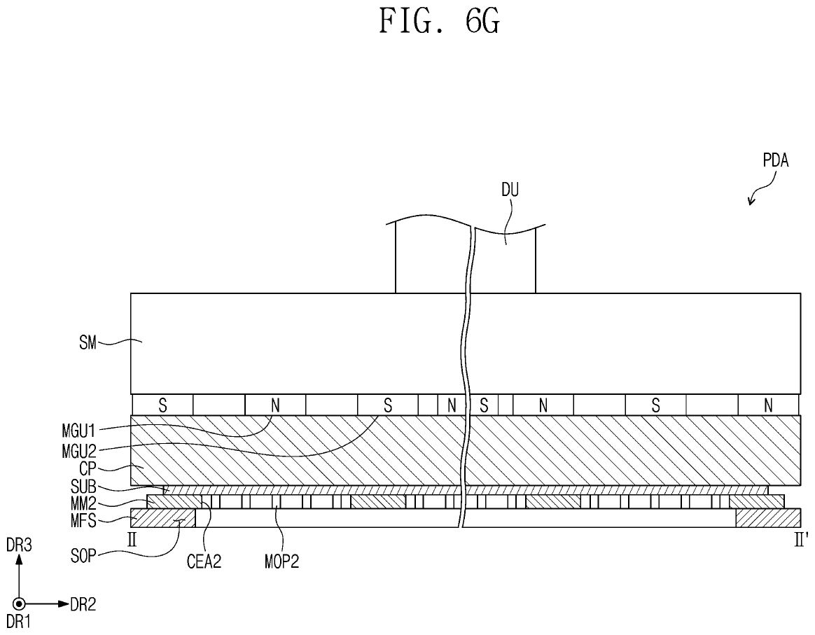

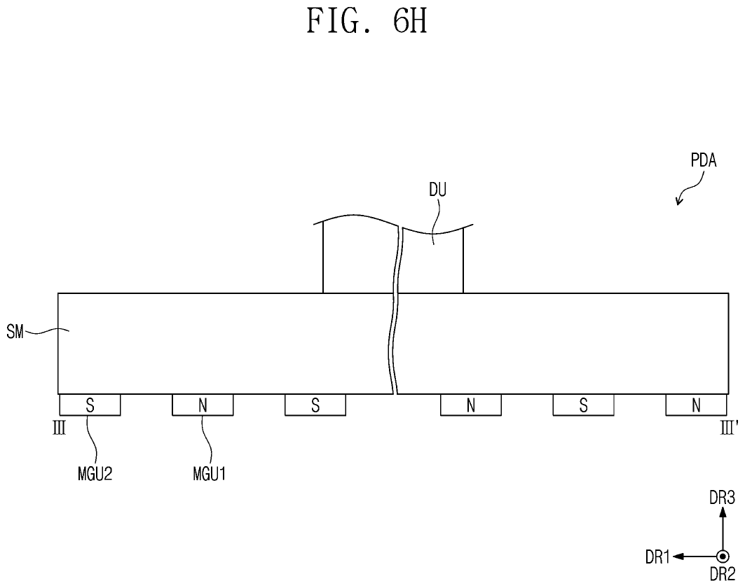

Although not shown in figures, the magnet plate SM may include ribs (not shown). The ribs (not shown) may be disposed on the lower surface of the magnet plate SM. The ribs (not shown) may move the magnet units MGU to the first direction DR1 or the second direction DR2. The movement of the magnet units MGU will be described in detail with reference to FIGS. 4D, 4E, and 6C to 6F.

The driving unit DU may be disposed on the magnet plate SM. The driving unit DU may be connected to the upper surface of the magnet plate SM. The driving unit DU may have a cylindrical shape extending in the third direction DR3. However, the shape of the driving unit DU should not be limited thereto or thereby and may have a variety of shapes. The driving unit DU may move the magnet plate SM back and force in the third direction DR3.

FIGS. 4A to 4F are views illustrating a method of depositing a deposition material on a substrate using the deposition apparatus PDA shown in FIG. 1.

As an example, FIG. 4A is a schematic perspective view, FIGS. 4B, 4C, and 4F are cross-sectional views taken along line I-I′ of FIG. 4A, and FIGS. 4D and 4E are schematic plan views showing a lower surface of the magnet plate SM.

In FIGS. 4A to 4F, an intersection direction may correspond to the first direction DR1, and one direction may correspond to the second direction DR2.

A driving unit DU, a magnet plate SM, a cooling plate CP, first masks MM1, and a mask frame MFS shown in FIGS. 4A to 4F are substantially the same as the driving unit DU, the magnet plate SM, the cooling plate CP, the first masks MM1, and the mask frame MFS shown in FIGS. 1 to 3, and thus, details thereof will be omitted.

Referring to FIG. 4A, the first masks MM1 may be fixed to the mask frame MFS. The first masks MM1 may extend in the one direction and may be arranged in the intersection direction. The substrate SUB may be disposed above the first masks MM1. The substrate SUB may be disposed between the first masks MM1 and the cooling plate CP. The substrate SUB may overlap the mask opening SOP.

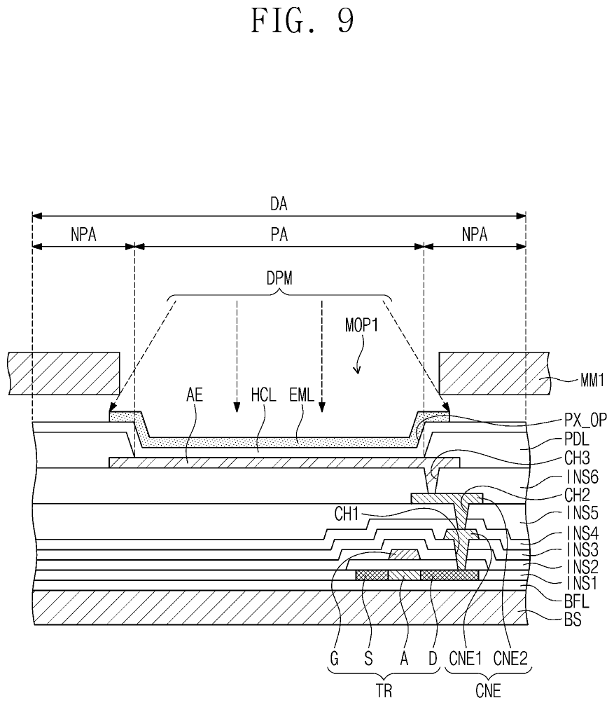

Although not shown in figures, a crucible in which the deposition material is accommodated may be disposed under or below the mask frame MFS. In case that the crucible is heated, the deposition material is vaporized, the vaporized deposition material may be provided to the substrate SUB via the mask opening SOP. This will be described in detail with reference to FIG. 9.

Referring to FIG. 4B, the substrate SUB may be disposed on the upper surface of the first masks MM1. The substrate SUB may be supported by the first masks MM1. In case that the mask frame MFS supports the substrate SUB and the first masks MM1, the first masks MM1 and the substrate SUB may be sagged by gravity. When viewed in the first direction DR1, the upper and lower surfaces of the first masks MM1 and the substrate SUB may have a curved shape.

Referring to FIG. 4C, in case that the substrate SUB is disposed on the upper surface of the first masks MM1, the cooling plate CP moves in the third direction DR3 and may be disposed adjacent to the substrate SUB. Although not shown in figures, the cooling plate CP may move back and forth in the third direction DR3 by a motor or the like within the spirit and the scope of the disclosure.

Although not shown in figures, a pipe through which a coolant flows may be disposed in the cooling plate CP. The substrate SUB may be in contact with the cooling plate CP in the deposition process. In a case where the substrate SUB is heated by the heated deposition material, the substrate SUB may be thermally deformed. However, since the coolant may be provided to the cooling plate CP that is in contact with the substrate SUB, the heated substrate SUB may be cooled by the coolant. Accordingly, the thermal deformation of the substrate SUB, which is caused by the heated deposition material, may be prevented.

Referring to FIGS. 4C, 4D, and 4E, in case that the cooling plate CP moves toward the substrate SUB, the magnet units MGU disposed on the lower surface of the magnet plate SM may move.

As shown in FIG. 4D, among the magnet units MGU, the magnet units MGU arranged in even-numbered rows may move in the one direction. The magnet units MGU arranged in the even-numbered rows may move in the second direction DR2. The magnet units MGU arranged in the even-numbered rows may move in the same direction as the extension direction of the first masks MM1. The row may correspond to the second direction DR2.

In an embodiment, the magnet units MGU arranged in the even-numbered rows among the magnet units MGU are described as moving, however, the disclosure should not be limited thereto or thereby.

As shown in FIG. 4E, the magnet units MGU arranged in odd-numbered rows may move in the one direction. The magnet units MGU arranged in odd-numbered rows may move in the second direction DR2. The magnet units MGU arranged in the odd-numbered rows may move in the same direction as the extension direction of the first masks MM1. The row may correspond to the second direction DR2.

Accordingly, the arrangement direction of the first magnet units MGU1 and the second magnet units MGU2 may be changed. The arrangement direction of the first magnet units MGU1 and the second magnet units MGU2 may be changed to a direction intersecting the extension direction of the first masks MM1.

As an example, the first magnet units MGU1 may be arranged in the intersection direction. The second magnet units MGU2 may be arranged in the intersection direction. For example, the first magnet units MGU1 may be arranged in the first direction DR1. The second magnet units MGU2 may be arranged in the first direction DR1.

The first magnet units MGU1 may be alternately arranged with the second magnet units MGU2 in the one direction. For example, the first magnet units MGU1 may be alternately arranged with the second magnet units MGU2 in the second direction DR2.

According to the above operation described with reference to FIGS. 4C, 4D, and 4E, the arrangement direction of the first magnet units MGU1 and the second magnet units MGU2 may intersect the extension direction of the first masks MM1.

Referring to FIG. 4F, in case that the polarities of the magnet units MGU facing the first masks MM1 are arranged in the direction intersecting the extension direction of the first masks MM1, the magnet plate SM may move in the third direction DR3 by the driving unit DU. In case that the magnet plate SM moves in the third direction DR3, the magnet plate SM may be disposed adjacent to the substrate SUB and the first masks MM1.

Some (or a number of) first magnet units MGU1 of the first magnet units MGU1 and some (or a number of) second magnet units MGU2 of the second magnet units MGU2 may overlap the first cell areas CEA1. Some first magnet units MGU1 of the first magnet units MGU1 and some second magnet units MGU2 of the second magnet units MGU2 may overlap the mask opening SOP.

In case that the magnet plate SM is disposed adjacent to the substrate SUB and the first masks MM1, an attractive force may be generated between the magnet units MGU and the first masks MM1. Accordingly, a center portion of the first masks MM1 may move toward the magnet units MGU. The substrate SUB disposed between the first masks MM1 and the magnet units MGU may be in contact with the lower surface of the cooling plate CP by the first masks MM1.

Accordingly, the first masks MM1 and the substrate SUB may be maintained in a flat state without being sagged. The deposition process may be performed. The deposition process will be described in detail later with reference to FIG. 9.

FIG. 5 is a schematic perspective view of a deposition apparatus PDA in which second masks MM2 are provided.

In FIG. 5, one direction may be defined as the first direction DR1, and an intersection direction may be defined as the second direction DR2.

Since a magnet plate SM, a driving unit DU, a cooling plate CP, and a mask frame MFS of FIG. 5 are substantially the same as the magnet plate SM, the driving unit DU, the cooling plate CP, and the mask frame MFS of FIG. 1 and a substrate SUB of FIG. 5 is substantially the same as the substrate SUB of FIG. 4A, descriptions thereof will be omitted or briefly provided.

Referring to FIG. 5, the second masks MM2 may be disposed on the mask frame MFS. Two sides of the second masks MM2 may be connected to the mask frame MFS. As an example, the second masks MM2 may be connected to the mask frame MFS by a laser welding method.

The second masks MM2 may extend in the first direction DR1 and may be arranged in the second direction DR2. The second masks MM2 may extend in the one direction and may be arranged in the intersection direction.

The second masks MM2 may include a metal material. As an example, each of the second masks MM2 may be a fine metal mask. Each of the second masks MM2 may have a rectangular shape with long sides in the first direction DR1 and short sides in the second direction DR2.

Each of the second masks MM2 may include second cell areas CEA2 defined in an upper surface thereof. As an example, two second cell areas CEA2 may be defined in the upper surface of each of the second masks MM2, however, the number of the second cell areas CEA2 should not be limited to two.

The second cell areas CEA2 may be arranged in the one direction. The second cell areas CEA2 may be arranged in the first direction DR1. When viewed in the plane, the second cell areas CEA2 may be arranged to overlap a mask opening SOP. When viewed in the plane, the second cell areas CEA2 may not overlap the mask frame MFS.

Each of the second cell areas CEA2 may have a polygonal shape. As an example, each of the second cell areas CEA2 may have a rectangular shape with long sides in the first direction DR1 and short sides in the second direction DR2.

Second cell openings MOP2 may be defined in each of the second cell areas CEA2. The second cell openings MOP2 may be arranged in the first direction DR1 and the second direction DR2. When viewed in the plane, the second cell openings MOP2 may overlap the mask opening SOP.

As an example, twenty-four second cell openings MOP2 may be defined in each of the second cell areas CEA2, however, the number of the second cell openings MOP2 should not be limited thereto or thereby.

Referring to FIGS. 1 and 5, a length in the first direction DR1 of the first masks MM1 may be smaller than a length in the second direction DR2 of the second masks MM2. A length in the first direction DR1 of the first cell areas CEA1 may be smaller than a length in the second direction DR2 of the second cell areas CEA2.

Since other components of the deposition apparatus PDA of FIG. 5 may have substantially the same structure and function as those of the deposition apparatus PDA described with reference to FIGS. 1 and 4A, details thereof will be omitted.

FIGS. 6A to 6H are views illustrating a method of depositing the deposition material on the substrate SUB using the deposition apparatus PDA shown in FIG. 5.

FIGS. 6A, 6B, and 6G are schematic cross-sectional views taken along line II-II′ of FIG. 5, FIGS. 6C to 6F are schematic plan views, and FIG. 6H is a schematic cross-sectional view taken along line III-III′ of FIG. 5.

In FIGS. 6A to 6H, the one direction may correspond to the first direction DR1, and the intersection direction may correspond to the second direction DR2.

FIG. 6H shows the magnet plate SM and magnet units MGU of FIG. 6G when viewed in a different direction from that of FIG. 6G.

For the convenience of explanation, FIG. 6H shows only the magnet plate SM and the driving unit DU.

Since the driving unit DU, the magnet plate SM, the cooling plate CP, and the mask frame MFS of FIGS. 6A to 6H are substantially the same as the driving unit DU, the magnet plate SM, the cooling plate CP, and the mask frame MFS of FIGS. 4A to 4F and the second masks MM2 of FIGS. 6A to 6H are substantially the same as the second masks MM2 of FIG. 5, descriptions thereof will be omitted or briefly provided.

Referring to FIG. 6A, the second masks MM2 may be fixed to the mask frame MFS. The second masks MM2 may extend in the one direction and may be arranged in the intersection direction. The second masks MM2 may extend in the first direction DR1 and may be arranged in the second direction DR2.

The substrate SUB may be disposed on an upper surface of the second masks MM2. The substrate SUB may overlap the mask opening SOP. The substrate SUB may be supported by the second masks MM2. In case that the mask frame MFS supports the substrate SUB and the second masks MM2, the second masks MM2 and the substrate SUB may be sagged by gravity. When viewed in the first direction DR1, the upper and lower surfaces of the second masks MM2 and the substrate SUB may have a curved shape.

Although not shown in figures, a crucible in which the deposition material is accommodated may be disposed under or below the mask frame MFS.

Referring to FIG. 6B, in case that the substrate SUB is disposed on the upper surfaces of the second masks MM2, the cooling plate CP may move in the third direction DR3 and may be disposed adjacent to the substrate SUB.

Although not shown in figures, a pipe through which a coolant flows may be disposed in the cooling plate CP.

Referring to FIGS. 6C to 6F, in case that the cooling plate CP of FIG. 6B moves, an arrangement direction of first magnet units MGU1 and second magnet units MGU2 may be changed.

In detail, as shown in FIG. 6C, the first and second magnet units MGU1 and MGU2 arranged in even-numbered rows may move in the second direction DR2. The first and second magnet units MGU1 and MGU2 arranged in the even-numbered rows may move in the intersection direction. The row may correspond to the second direction DR2.

After the first and second magnet units MGU1 and MGU2 move in the second direction DR2, the first and second magnet units MGU1 and MGU2 may be disposed in a first area A1, a second-third area A2-3, and a second-fourth area A2-4 as shown in FIG. 6D. The first and second magnet units MGU1 and MGU2 may be alternately arranged with each other in the first direction DR1 and the second direction DR2. The first and second magnet units MGU1 and MGU2 may be alternately arranged in the one direction and the intersection direction.

Some (or a number of) magnet units MGU of the magnet units MGU may move in the same direction as the extension direction of the second masks MM2.

As shown in FIG. 6E, among the magnet units MGU, the magnet units MGU arranged in even-numbered columns may move in the one direction. The magnet units MGU arranged in the even-numbered columns may move in the first direction DR1. The magnet units MGU arranged in the even-numbered columns may move in the same direction as the extension direction of the second masks MM2. The column may correspond to the first direction DR1.

In an embodiment, the magnet units MGU arranged in the even-numbered rows among the magnet units MGU are described as moving, however, the disclosure should not be limited thereto or thereby.

As shown in FIG. 6F, the magnet units MGU arranged in odd-numbered columns may move in the one direction. The magnet units MGU arranged in the odd-numbered columns may move in the first direction DR1. The magnet units MGU arranged in the odd-numbered columns may move in the same direction as the extension direction of the second masks MM2. The column may correspond to the first direction DR1.

Accordingly, the arrangement direction of the first magnet units MGU1 and the second magnet units MGU2 may be changed. The arrangement direction of the first magnet units MGU1 and the second magnet units MGU2 may be changed to a direction intersecting the extension direction of the second masks MM2.

As an example, the first magnet units MGU1 may be arranged in the intersection direction. The second magnet units MGU2 may be arranged in the intersection direction. For example, the first magnet units MGU1 may be arranged in the second direction DR2. The second magnet units MGU2 may be arranged in the second direction DR2.

The first magnet units MGU1 and the second magnet units MGU2 may be alternately arranged with each other in the one direction. For example, the first magnet units MGU1 and the second magnet units MGU2 may be alternately arranged with each other in the first direction DR1.

According to the above operation described with reference to FIGS. 6C, 6D, and 6E, the arrangement direction of the first magnet units MGU1 and the second magnet units MGU2 may intersect the extension direction of the second masks MM2.

In a case where the arrangement direction of the first magnet units MGU1 and the second magnet units MGU2 is fixed, only one of the first masks MM1 and the second masks MM2 may be used in the deposition apparatus PDA. As an example, in a case where each of the first and second magnet units MGU1 and MGU2 of the deposition apparatus PDA (refer to FIG. 1) is arranged in the first direction DR1, the deposition process may be performed using the first masks MM1 (refer to FIG. 1). However, in a case where the deposition process is performed using the second masks MM2 (refer to FIG. 5), the extension direction of the second masks MM2 (refer to FIG. 5) may be substantially the same as the extension direction of the first and second magnet units MGU1 and MGU2. Therefore, a repulsive force may be generated between the second masks MM2 (refer to FIG. 5) and the first magnet units MGU1 and between the second masks MM2 (refer to FIG. 5) and the second magnet units MGU2. In case that the deposition process is performed, the second masks MM2 (refer to FIG. 5) and the substrate SUB (refer to FIG. 5) may not be tightly attached to each other due to the repulsive force, and thus, defects may occur.

However, according to the disclosure, as the first magnet units MGU1 and the second magnet units MGU2 move in the same direction as the extension direction of the masks MM1 and MM2, the arrangement direction of the first and second magnet units MGU1 and MGU2 may be changed.

As an example, in the case where the deposition process is performed using the first masks MM1 (refer to FIG. 1), some magnet units MGU of the magnet units MGU may move. Accordingly, the arrangement direction of the first and second magnet units MGU1 and MGU2 may intersect the extension direction of the first masks MM1 (refer to FIG. 1).

In the case where the deposition process is performed using the second masks MM2, some magnet units MGU of the magnet units MGU may move. Accordingly, the arrangement direction of the first and second magnet units MGU1 and MGU2 may intersect the extension direction of the second masks MM2 (refer to FIG. 5).

Accordingly, in case that the deposition process is performed, the repulsive force may not be generated between the masks MM1 and MM2 and the magnet units MGU regardless of the extension direction of the masks MM1 and MM2, and thus, defects may be reduced.

Referring to FIGS. 6G and 6H, in case that polarities of the magnet units MGU facing the second masks MM2 are arranged in a direction intersecting the extension direction of the second masks MM2, the magnet plate SM may move in the third direction DR3 and may be disposed adjacent to the substrate SUB and the second masks MM2.

Some first magnet units MGU1 of the first magnet units MGU1 and some second magnet units MGU2 of the second magnet units MGU2 may overlap the second cell areas CEA2. Some first magnet units MGU1 of the first magnet units MGU1 and some second magnet units MGU2 of the second magnet units MGU2 may overlap the mask opening SOP.

In case that the magnet plate SM is disposed adjacent to the substrate SUB and the second masks MM2, an attractive force may be generated between the magnet units MGU and the second masks MM2. Accordingly, a center portion of the second masks MM2 may move toward the magnet units MGU. The substrate SUB disposed between the second masks MM2 and the magnet units MGU may be in contact with a lower surface of the cooling plate CP by the second masks MM2.

Accordingly, the second masks MM2 and the substrate SUB may be maintained in the flat state without being sagged downward. The deposition process may be performed. The deposition process will be described in detail with reference to FIG. 9.

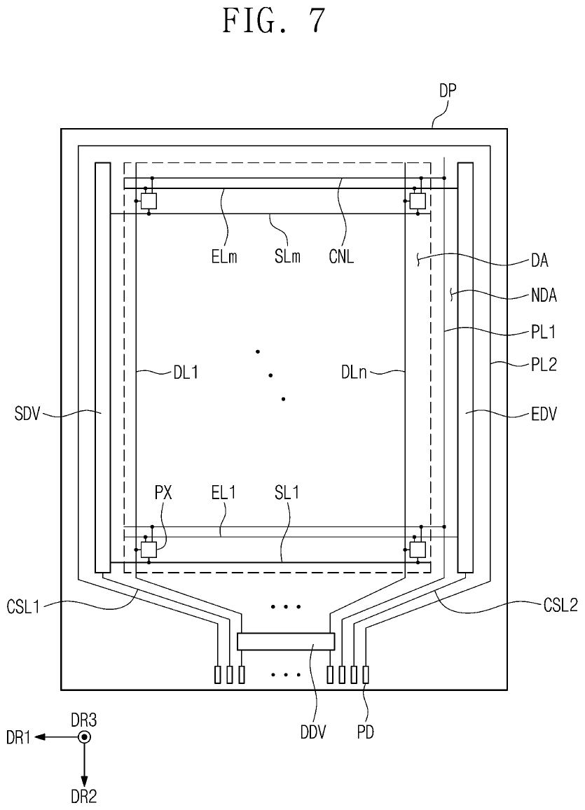

FIG. 7 is a schematic plan view of a display panel DP manufactured using the masks shown in FIGS. 1 and 5.

Referring to FIG. 7, the display panel DP may have a rectangular shape defined by short sides extending in the first direction DR1 and long sides extending in the second direction DR2, however, the shape of the display panel DP should not be limited to the rectangular shape. The display panel DP may include a display part DA and a non-display part NDA surrounding or adjacent to the display part DA.

The display panel DP may be a light emitting type display panel. For instance, the display panel DP may be an organic light emitting display panel or a quantum dot light emitting display panel. A light emitting layer of the organic light emitting display panel may include an organic light emitting material. A light emitting layer of the quantum dot light emitting display panel may include a quantum dot or a quantum rod. Hereinafter, the organic light emitting display panel will be described as a representative example of the display panel DP.

The display panel DP may include pixels PX, scan lines SL1 to SLm, data lines DL1 to DLn, emission lines EL1 to Elm, first and second control lines CSL1 and CSL2, first and second power lines PL1 and PL2, connection lines CNL, and pads PD. Each of “m” and “n” is a natural number.

The pixels PX may be arranged in the display part DA. A scan driver SDV and an emission driver EDV may be disposed in the non-display part NDA respectively adjacent to the long sides of the display panel DP. A data driver DDV may be disposed in the non-display part NDA adjacent to one short side of the short sides of the display panel DP. When viewed in the plane, the data driver DDV may be disposed adjacent to a lower end of the display panel DP.

The scan lines SL1 to SLm may extend in the first direction DR1 and may be connected to the pixels PX and the scan driver SDV. The data lines DL1 to DLn may extend in the second direction DR2 and may be connected to the pixels PX and the data driver DDV. The emission lines EL1 to ELm may extend in the first direction DR1 and may be connected to the pixels PX and the emission driver EDV.

The first power line PL1 may extend in the second direction DR2 and may be disposed in the non-display part NDA. The first power line PL1 may be disposed between the display part DA and the emission driver EDV, however, it should not be limited thereto or thereby. According to an embodiment, the first power line PL1 may be disposed between the display part DA and the scan driver SDV.

The connection lines CNL may extend in the first direction DR1 and may be arranged in the second direction DR2. The connection lines CNL may be connected to the first power line PL1 and the pixels PX. A first voltage may be applied to the pixels PX through the first power line PL1 and the connection lines CNL connected to the first power line PL1.

The second power line PL2 may be disposed in the non-display part NDA. The second power line PL2 may extend along the long sides of the display panel DP and the other short side at which the data driver DDV is not disposed in the display panel DP. The second power line PL2 may be disposed outside the scan driver SDV and the emission driver EDV.

Although not shown in figures, the second power line PL2 may extend to the display part DA and may be connected to the pixels PX. A second voltage having a level lower than that of the first voltage may be applied to the pixels PX through the second power line PL2.

The first control line CSL1 may be connected to the scan driver SDV and may extend toward the lower end of the display panel DP when viewed in the plane. The second control line CSL2 may be connected to the emission driver EDV and may extend toward the lower end of the display panel DP when viewed in the plane. The data driver DDV may be disposed between the first control line CSL1 and the second control line CSL2.

The pads PD may be disposed on the display panel DP. The pads PD may be disposed closer to the lower end of the display panel DP than the data driver DDV is. The data driver DDV, the first power line PL1, the second power line PL2, the first control line CSL1, and the second control line CSL2 may be connected to the pads PD. The data lines DL1 to DLn may be connected to the data driver DDV, and the data driver DDV may be connected to the pads PD corresponding to the data lines DL1 to DLn.

Each of the first and second cell areas CEA1 and CEA2 shown in FIGS. 1 and 5 may correspond to the display panel DP shown in FIG. 7. Light emitting elements of one display panel DP may be formed by one first cell area CEA1 or one second cell area CEA2.

Unit areas each corresponding to the display panel DP may be defined in the substrate SUB. In case that the light emitting elements are formed in each of the unit areas, the substrate SUB may be cut for each unit area. Therefore, the display panel DP shown in FIG. 7 may be manufactured.

Although not shown in figures, a timing controller to control an operation of the scan driver SDV, the data driver DDV, and the emission driver EDV and a voltage generator to generate the first and second voltages may be disposed on a printed circuit board. The timing controller and the voltage generator may be connected to corresponding pads PD through the printed circuit board.

The scan driver SDV may generate scan signals, and the scan signals may be applied to the pixels PX through the scan lines SL1 to SLm. The data driver DDV may generate data voltages, and the data voltages may be applied to the pixels PX through the data lines DL1 to DLn. The emission driver EDV may generate emission signals, and the emission signals may be applied to the pixels PX through the emission lines EL1 to ELm.

The pixels PX may receive the data voltages in response to the scan signals. The pixels PX may emit a light having a luminance corresponding to the data voltages in response to the emission signals, and thus, the image may be displayed. An emission time of the pixels PX may be controlled by the emission signals.

The lines may include the data lines DL1 to DLn. The pads connected to the above-described lines may include the pads PD shown in FIG. 7. The display panel DP in which the light emitting layers of the pixels PX are not formed may be defined as the substrate SUB.

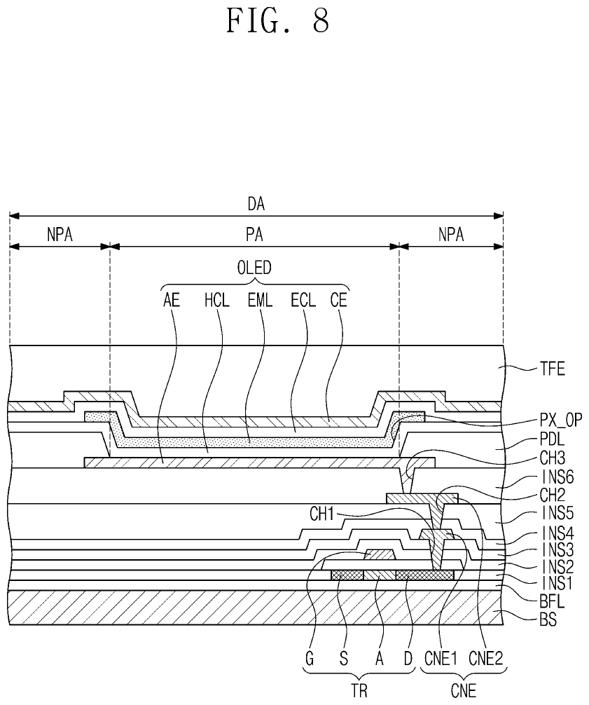

A structure of the substrate SUB in which the light emitting layers are not formed will be described with reference to FIG. 8. The pads PD may be formed in the substrate SUB, and the substrate SUB may be in a state where the printed circuit board is not connected. The pads PD may be grounded to the data lines DL1 to DLn.

FIG. 8 is a schematic cross-sectional view of the pixel PX shown in FIG. 7.

Referring to FIGS. 7 and 8, the pixel PX may be disposed on a base substrate BS and may include a transistor TR and a light emitting element OLED. The transistors TR and the light emitting elements OLED of the pixels PX may be connected to the data lines DL1 to DLn and the first and second power lines PL1 and PL2.

The transistors TR and the light emitting elements OLED of the pixels PX may be connected to the pads PD of FIG. 7 via the data lines DL1 to DLn (refer to FIG. 7) and the first and second power lines PL1 and PL2 (refer to FIG. 7). The transistors TR of the pixels PX may be connected to the pads PD of FIG. 7 via the data lines DL1 to DLn (refer to FIG. 7).

The light emitting element OLED may include a first electrode AE, a second electrode CE, a hole control layer HCL, an electron control layer ECL, and a light emitting layer EML. The first electrode AE may be an anode electrode, and the second electrode CE may be a cathode electrode.

The transistor TR and the light emitting element OLED may be disposed on the base substrate BS. As an example, one transistor TR is shown in FIG. 8, however, the pixel PX may include transistors and at least one capacitor to drive the light emitting element OLED.

The display part DA may include a light emitting area PA corresponding to each pixel PX and a non-light-emitting area NPA around the light emitting area PA. The light emitting element OLED may be disposed in the light emitting area PA.

The base substrate BS may include a flexible plastic substrate. As an example, the base substrate BS may include transparent polyimide (PI). A buffer layer BFL may be disposed on the base substrate BS, and the buffer layer BFL may be an inorganic layer.

A semiconductor pattern may be disposed on the buffer layer BFL. The semiconductor pattern may include polycrystalline silicon, however, it should not be limited thereto or thereby. According to an embodiment, the semiconductor pattern may include amorphous silicon or metal oxide.

The semiconductor pattern may be doped with an N-type dopant or a P-type dopant. The semiconductor pattern may include a high-doped region and a low-doped region. The high-doped region may have a conductivity greater than that of the low-doped region and may substantially serve as a source electrode and a drain electrode of the transistor TR. The low-doped region may substantially correspond to an active (or a channel) of the transistor TR.

A source S, an active A, and a drain D of the transistor TR may be formed from the semiconductor pattern. A first insulating layer INS1 may be disposed on the semiconductor pattern. A gate G of the transistor TR may be disposed on the first insulating layer INS1. A second insulating layer INS2 may be disposed on the gate G. A third insulating layer INS3 may be disposed on the second insulating layer INS2.

A connection electrode CNE may be disposed between the transistor TR and the light emitting element OLED to connect the transistor TR to the light emitting element OLED. The connection electrode CNE may include a first connection electrode CNE1 and a second connection electrode CNE2.

The first connection electrode CNE1 may be disposed on the third insulating layer INS3 and may be connected to the drain D via a first contact hole CH1 defined through the first, second, and third insulating layers INS1, INS2, and INS3. A fourth insulating layer INS4 may be disposed on the first connection electrode CNE1. A fifth insulating layer INS5 may be disposed on the fourth insulating layer INS4.

The second connection electrode CNE2 may be disposed on the fifth insulating layer INS5. The second connection electrode CNE2 may be connected to the first connection electrode CNE1 via a second contact hole CH2 defined through the fourth insulating layer INS4 and the fifth insulating layer INS5. A sixth insulating layer INS6 may be disposed on the second connection electrode CNE2. Each of the first to sixth insulating layers INS1 to INS6 may be an inorganic layer or an organic layer.

The first electrode AE may be disposed on the sixth insulating layer INS6. The first electrode AE may be connected to the second connection electrode CNE2 via a third contact hole CH3 defined through the sixth insulating layer INS6. A pixel definition layer PDL may be disposed on the first electrode AE and the sixth insulating layer INS6 to expose a selectable portion of the first electrode AE. The pixel definition layer PDL may be provided with an opening PX_OP defined therethrough to expose the portion of the first electrode AE.

The hole control layer HCL may be disposed on the first electrode AE and the pixel definition layer PDL. The hole control layer HCL may be commonly disposed in the light emitting area PA and the non-light-emitting area NPA. The hole control layer HCL may include a hole transport layer and a hole injection layer.

The light emitting layer EML may be disposed on the hole control layer HCL. The light emitting layer EML may be disposed in an area corresponding to the opening PX_OP. The light emitting layer EML may include an organic material and/or an inorganic material. The light emitting layer EML may generate a light having one of red, green, and blue colors.

The electron control layer ECL may be disposed on the light emitting layer EML and the hole control layer HCL. The electron control layer ECL may be commonly disposed in the light emitting area PA and the non-light-emitting area NPA. The electron control layer ECL may include an electron transport layer and an electron injection layer.

The second electrode CE may be disposed on the electron control layer ECL. The second electrode CE may be commonly disposed over the pixels PX.

A thin film encapsulation layer TFE may be disposed on the light emitting element OLED. The thin film encapsulation layer TFE may be disposed on the second electrode CE to cover the pixel PX. The thin film encapsulation layer TFE may include at least two inorganic layers and organic layers disposed between the inorganic layers. The inorganic layers may protect the pixel PX from moisture and oxygen. The organic layers may protect the pixel PX from a foreign substance such as dust particles.

The first voltage may be applied to the first electrode AE via the transistor TR, and the second voltage having the level lower than the first voltage may be applied to the second electrode CE. Holes and electrons injected into the light emitting layer EML may be recombined to generate excitons, and the light emitting element OLED may emit the light by the excitons that return to a ground state from an excited state.

FIG. 9 is a schematic cross-sectional view illustrating the deposition process shown in FIG. 4F.

For the convenience of explanation, the substrate SUB and the first masks MM1 shown in FIG. 4F are shown upside down in FIG. 9.

Referring to FIGS. 4F and 9, the deposition process performed using the first masks MM1 is shown as an example, however, it should not be limited thereto or thereby. According to an embodiment, the deposition material may be deposited on the substrate SUB through the second masks MM2.

The layers from the base substrate BS to the first electrode AE may be defined as the substrate SUB. As described above, the transistor TR may be connected to the pads PD via the data lines DL1 to DLn. For example, the substrate SUB may include the data lines DL1 to DLn defined by the above-described lines and the pads PD connected to the data lines DL1 to DLn.

The first masks MM1 may be disposed to face the substrate SUB. The first masks MM1 may be disposed adjacent to the substrate SUB. The deposition material DPM may be provided on the substrate SUB via the first cell opening MOP1 defined through the first masks MM1. FIG. 9 shows the first cell openings MOP1 as a representative example, however, in a case where the second masks MM2 are used, the deposition material DPM may be provided on the substrate SUB via the second cell opening MOP2. The light emitting layer EML may be formed on the substrate SUB using the deposition material DPM.

Although embodiments have been described, it is understood that the disclosure should not be limited to these embodiments but various changes and modifications can be made by one of ordinary skill in the art within the spirit and scope of the disclosure and as hereinafter claimed. Therefore, the disclosed subject matter should not be limited to any single embodiment described herein, and the scope of the disclosure shall be determined according to the attached claims.

What is claimed is:

1. A deposition apparatus comprising:
a mask frame having a frame shape;
a plurality of masks disposed on the mask frame, extending in a selected direction, disposed in an intersection direction intersecting the selected direction, and each of the plurality of masks including cell areas;
a magnet plate disposed on the plurality of masks; and
a plurality of magnet parts connected to a lower surface of the magnet plate,
wherein at least one of the plurality of magnet parts moves in the selected direction.

2. The deposition apparatus of claim 1, wherein the plurality of magnet parts comprise:
a plurality of first magnet parts disposed to allow first polarities of the plurality of first magnet parts to face the plurality of masks; and
a plurality of second magnet parts disposed to allow second polarities of the plurality of second magnet parts to face the plurality of masks, and the plurality of first magnet parts and the plurality of second magnet parts are disposed in the selected direction and the intersection direction before the at least one of the plurality of magnet parts moves.

3. The deposition apparatus of claim 2, wherein in case that the at least one of the plurality of magnet parts moves, the plurality of first magnet parts overlapping the cell areas are disposed in the intersection direction, the plurality of second magnet parts overlapping the cell areas are disposed in the intersection direction, and the plurality of first magnet parts are alternately disposed with the plurality of second magnet parts in the selected direction.

4. The deposition apparatus of claim 3, wherein
the intersection direction is defined as a first direction,
the selected direction is defined as a second direction,
the plurality of first magnet parts and the plurality of second magnet parts disposed in even-numbered rows among rows corresponding to the second direction move in the second direction, and
the second direction corresponds to the even-numbered rows.

5. The deposition apparatus of claim 4, wherein in case that the plurality of first magnet parts and plurality of second magnet parts disposed in the even-numbered rows move in the second direction,
the plurality of first magnet parts are disposed in the first direction,
the plurality of second magnet parts are disposed in the first direction, and
the plurality of first magnet parts are alternately disposed with the plurality of second magnet parts in the second direction.

6. The deposition apparatus of claim 3, wherein
the intersection direction is defined as a first direction,
the selected direction is defined as a second direction,
the plurality of first magnet parts and the plurality of second magnet parts disposed in odd-numbered rows among rows corresponding to the second direction move in the second direction, and
the second direction corresponds to the odd-numbered rows.

7. The deposition apparatus of claim 6, wherein in case that the plurality of first magnet parts and the plurality of second magnet parts in the odd-numbered rows move in the second direction,
the plurality of first magnet parts are disposed in the first direction,
the plurality of second magnet parts are disposed in the first direction, and
the plurality of first magnet parts are alternately disposed with the second magnet parts in the second direction.

8. The deposition apparatus of claim 3, wherein
the selected direction is defined as a first direction,
the intersection direction is defined as a second direction,
the plurality of first magnet parts and the plurality of second magnet parts disposed in even-numbered columns among columns corresponding to the first direction move in the first direction, and
the first direction corresponds to the even-numbered columns.

9. The deposition apparatus of claim 8, wherein in case that the plurality of first magnet parts and the plurality of second magnet parts disposed in the even-numbered columns move in the first direction,
the plurality of first magnet parts are disposed in the second direction,
the plurality of second magnet parts are disposed in the second direction, and
the plurality of first magnet parts are alternately disposed with the plurality of second magnet parts in the first direction.

10. The deposition apparatus of claim 3, wherein
the selected direction is defined as a first direction, the intersection direction is defined as a second direction,
the plurality of first magnet parts and the plurality of second magnet parts disposed in odd-numbered columns among columns corresponding to the first direction move in the first direction, and
the first direction corresponds to the odd-numbered columns.

11. The deposition apparatus of claim 10, wherein in case that the plurality of first magnet parts and the plurality of second magnet parts disposed in the odd-numbered columns move in the first direction,
the plurality of first magnet parts are disposed in the second direction,
the plurality of second magnet parts are disposed in the second direction, and
the plurality of first magnet parts are alternately disposed with the plurality of second magnet parts in the first direction.

12. The deposition apparatus of claim 2, wherein the plurality of first magnet parts have a same area as the plurality of second magnet parts in a plan view.

13. The deposition apparatus of claim 1, further comprising:
a cooling plate disposed between the plurality of masks and the magnet plate.

14. The deposition apparatus of claim 1, further comprising:
a driver connected to an upper surface of the magnet plate and extending in a direction intersecting the selected direction and the intersection direction.

15. A deposition apparatus comprising:
a mask frame having a frame shape;
a plurality of masks disposed on the mask frame, extending in a selected direction, disposed in an intersection direction intersecting the selected direction, and each of the plurality of masks including cell areas;
a magnet plate disposed on the plurality of masks; and
a plurality of magnet parts connected to a lower surface of the magnet plate, the plurality of magnet parts comprising:
a plurality of first magnet parts disposed to allow first polarities thereof to face the plurality of masks; and
a plurality of second magnet parts disposed to allow the second polarities thereof to face the plurality of masks,
wherein a direction in which the plurality of first magnet parts and the plurality of second magnet parts are disposed is changed.

16. The deposition apparatus of claim 15, wherein the plurality of first magnet parts and the plurality of second magnet parts are arranged in the selected direction and the intersection direction before an arrangement direction of the plurality of first magnet parts and the plurality of second magnet parts is changed.

17. The deposition apparatus of claim 16, wherein the plurality of first magnet parts and the plurality of second magnet parts move in the selected direction in case that the arrangement direction of the plurality of first magnet parts and the plurality of second magnet parts is changed.

18. The deposition apparatus of claim 17, wherein in case that the arrangement direction of the plurality of first magnet parts and the plurality of second magnet parts is changed,
the plurality of first magnet parts are disposed in the intersection direction,
the plurality of second magnet parts are disposed in the intersection direction, and
the plurality of first magnet parts are alternately disposed with the plurality of second magnet parts in the selected direction.

19. The deposition apparatus of claim 18, wherein
the intersection direction is defined as a first direction,
the selected direction is defined as a second direction, and
in case that the arrangement direction of the plurality of first magnet parts and the plurality of second magnet parts is changed, the plurality of first magnet parts are disposed in the first direction, the plurality of second magnet parts are disposed in the first direction, and the plurality of first magnet parts are alternately arranged with the plurality of second magnet parts in the second direction.

20. The deposition apparatus of claim 18, wherein
the selected direction is defined as a first direction,
the intersection direction is defined as a second direction, and
in case that the arrangement direction of the plurality of first magnet parts and the plurality of second magnet parts is changed, the plurality of first magnet parts are arranged in the second direction, the plurality of second magnet parts are disposed in the second direction, and the plurality of first magnet parts are alternately arranged with the plurality of second magnet parts in the first direction.
